(19) United States
(12) Patent Application Publication
(10) Pub. No.: US 2009/0004852 A1
(43) Pub. Date: Jan. 1, 2009

(54) Nanostructures Containing Metal Semiconductor Compounds

(75) Inventors: Charles M. Lieber, Lexington, MA (US); Yue Wu, Cambridge, MA (US); Jie Xiang, Cambridge, MA (US); Chen Yang, Somerville, MA (US); Wei Lu, Ann Arbor, MI (US)

Correspondence Address: WOLF GREENFIELD & SACKS, P.C., 600 ATLANTIC AVENUE, BOSTON, MA, 02210-2206, US

(73) Assignee: President and Fellows of Havard College, Cambridge, MA (US)

(21) Appl. No.: 10/588,833

(22) PCT Filed: Dec. 9, 2005
(86) PCT No.: PCT/US05/44559

§ 371 Date: Sep. 2, 2008

(30) Foreign Application Priority Data
Dec. 21, 2004 (US) 11018299

(51) Int. Cl. H01L 21/44

(52) U.S. Cl. 438/664; 257/E21.199

(57) ABSTRACT

A network element (10), such as a Packet Data Serving Node, detects (31) a change in operational status of a mobile station during a communication session and, in response to detecting such a change, automatically increases (32) memory capacity as is available to support additional communication sessions while simultaneously persisting at least some session information for potential subsequent use during the communication session. For example, this response can occur upon detecting that a mobile station has changed from an active to a dormant status. Then, upon returning to an active status, the network element can use the persisted information to facilitate rapid reconstruction of infrastructure support for the mobile station's call participation.

### TECHNICAL FIELD

This invention relates generally to call processing in a communication system and more particularly to memory management of call-related information.

### BACKGROUND

Using a network element such as a Packet Data Serving Node (PDSN) to facilitate a communication is well known in the art. This includes, in more recent times, supporting communication sessions such as voice and/or data calls as between two or more parties. In many cases, the number of calls that a given network element can support at any given time is less than the network as a whole might otherwise support. As a result, a plurality of such network elements are typically deployed in order to make effective use of a given network's available resources.

There are, however, various causes contributing to the limited call capacity of a network element. One important causative agent comprises available memory. To illustrate, when a new call arrives at a Packet Data Serving Node, different modules as comprise the Packet Data Serving Node each allocate memory to store corresponding call context information. A not untypical Packet Data Serving Node chassis, for example, allocates about 30 KB of memory for each call for these purposes. As a result, many Packet Data Serving Nodes can only support a maximum of about 40,000 calls per card.

One can, of course, increase available memory by increasing the available quantity of memory. In many cases, however, this approach is unattractive. Increasing memory may, in some cases, be physically impossible. In other cases it may represent an unacceptable increase in cost.

### BRIEF DESCRIPTION OF THE DRAWINGS

The above needs are at least partially met through provision of the method and apparatus to increase session capacity described in the following detailed description, particularly when studied in conjunction with the drawings, wherein:

FIG. 1 comprises a block diagram as configured in accordance with various embodiments of the invention;

FIG. 2 comprises a schematic representation as configured in accordance with various embodiments of the invention;

FIG. 3 comprises a flow diagram as configured in accordance with various embodiments of the invention;

FIG. 4 comprises a schematic representation as configured in accordance with various embodiments of the invention; and

FIG. 5 comprises a schematic representation as configured in accordance with various embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention. It will also be understood that the terms and expressions used herein have the ordinary meaning as is usually accorded to such terms and expressions by those skilled in the corresponding respective areas of inquiry and study except where other specific meanings have otherwise been set forth herein.

### DETAILED DESCRIPTION

Generally speaking, pursuant to these various embodiments, an enabling process detects a change in the operational status of a mobile station during a communication session and, in response to detecting that change, automatically increases memory capacity that is available to support additional communication sessions while simultaneously persisting at least some session information from that communication session for potential subsequent use during that communication session.

In a preferred approach, this process detects, in particular, a change in operational status from an active status to a dormant status though other approaches are available and may be preferable in a given setting.

There are, also, various ways to effect the indicated increase in memory capacity. Pursuant to one approach, some, but not all, session context information as corresponds to that communication session is deleted. The retained session context information is then stored. This stored information can then be quickly retrieved should the mobile station again become active in this communication session. Pursuant to a related approach, the retained session content information (in whole or in part) can be compressed prior to storing such information.

So configured, critical and/or useful session content information can persist and be available to quickly facilitate subsequent participation of the mobile station in a given communication session while also effecting a dynamic and significant increase in the quantity of available memory. This, in turn, can lead to a significant increase in the number of calls that can be supported by a given network element as the average storage requirements per call will typically drop.

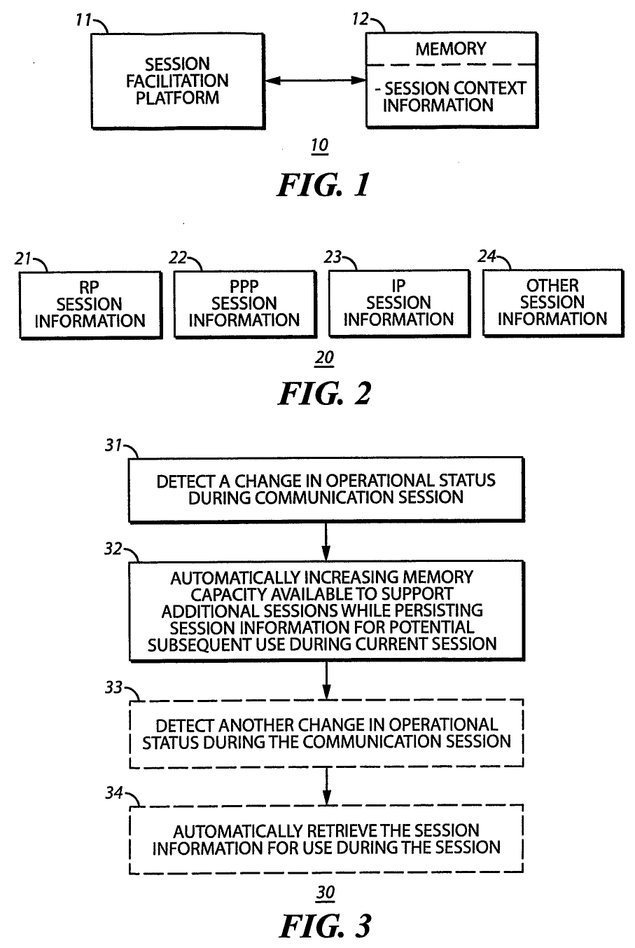

These and other benefits may become more evident upon making a thorough review and study of the following detailed description. Referring now to the drawings, and in particular to FIG. 1, these teachings can be implemented in various ways but are preferably, at this time, carried forth by a network element 10 such as, but not limited to, a Packet Data Serving Node, a Serving General Packet Radio Service (GPRS) Support Node, a Home Agent, a Gateway GPRS Support Node, and the like. Such a network element 10 comprises, in relevant part, a communication session facilitation platform 11 that operably couples to (or includes, in whole or in part) a memory 12.

The memory 12 has session context information stored therein. More particularly, and as will be explained below in more detail, from time to time and during the course of a given communication session for a given mobile station, this session context information comprises an incomplete set of session context information as corresponds to that communication session. In a preferred approach, this incomplete set of session context information comprises, at the least, a minimal necessary subset of information as is necessary to facilitate subsequent restoration of a given call.

This memory 12 can be realized in any of a wide variety of ways. For example, this memory 12 can comprise a centralized storage platform or, if desired, the storage role can be distributed over a larger number of platforms. Further, this memory can be integral to the network element 10 or, if desired, some or all of the storage role described herein can be assigned to a more remotely located memory. Such architectural options are well understood in the art and require no further description here.

Network elements, including Packet Data Serving Nodes, typically comprise a partially or wholly programmable platform. Those skilled in the art will recognize and understand that such a platform can be readily programmed, configured, and arranged to accord with these teachings. More particularly, this programming and/or configuration can comprise provision of a session facilitation platform 11 that can detect a change in operational status of a given mobile station during the course of a communication session and, in response to detecting that change, automatically increase memory capacity that is available to support additional communication sessions while simultaneously persisting some session information for potential subsequent use during the communication session. More particularly, in a preferred approach the session facilitation platform 11 stores such session information in the memory 12 as the incomplete set of session context information noted above.

Further, and also pursuant to a preferred approach, the session facilitation platform 11 can also detect another change in the operational status of the given mobile station during that communication session (such as, and again as will be described below in more detail, a change from a dormant to an active mode of operation) and, in response to detecting that change, can automatically retrieve the incomplete set of session information for use during the communication session to at least substantially recreate a complete session context for the given mobile station.

With reference to FIG. 2, the session context information 20 will of course vary from application to application. In a not untypical setting, however, such session context information 20 will comprise Radio Network Node (RNN) to Packet Data Serving Node (PDSN) (RP) protocol session information 21 (such as, but not limited to user name, Packet Control Function addressing, GRE key values, IMSI values, and the like), Point-to-Point Protocol (PPP) session information 22 (such as, but not limited to, Link Control Protocol information, ACCM mapping, compression values or information, Domain Name server values, and the like), Internet Protocol (IP) session information 23 (such as, but not limited to IP addresses, internal state information, and the like), and such other session information 24 as may be relevant and applicable in a given setting (such as, but not limited to, mobile IP flags and/or identification, accounting information (regarding, for example, prepaid services, roaming arrangements, quality of service, and so forth), and the like). Such session context information comprises a generally well-understand aspect of present practice and therefore additional elaboration will not be provided here for the sake of brevity.

Referring now to FIG. 3, these teachings encompass generally a process 30 that provides for detection 31 of a change in the operational status of a mobile station during a communication session. This change can constitute, for example, a change in operational status from active status to dormant status. There are various ways by which this process 10 can effect such detection. For example, if desired, locally stored non-compressed triggering information can be employed for this purpose. As another example, this process 10 can access presence information regarding the mobile station (as may be available, for example, via a presence server) when such presence information reflects the operational change of interest.

As yet another example, this detection can comprise receiving a message indicating the change in operational status. For example, the enabling network element can receive a Radio Network Node (RNN) to Packet Data Serving Node (PDSN) (RP) protocol compatible message in this regard (such as, to illustrate, an ACTIVE_STOP message over an A11 control channel, though other parameters will do doubt be appropriate to use to generate such a trigger in other systems as will be well understood by those skilled in the art).

As yet another example, this detection can comprise detecting the conclusion of an inactivity duration of time. To illustrate, the network element (or a surrogate acting on its behalf) can initiate a timer (by beginning a countdown or incrementing a count) upon detecting inactivity on the part of the mobile station. When that timer concludes, the persistent inactivity of the mobile station can be used to detect the mobile station as now being in a dormant state of operation.

Other possibilities exist as well. For example, historical information (regarding, for example, the active and inactive behaviors of the mobile station) may also be used to inform, directly or indirectly, such a detection process.

This process 30 then provides for automatically increasing 32 memory capacity that is available to support available communication sessions while simultaneously persisting at least some session information for potential subsequent use during the communication session. Memory capacity can be so increased using any of a wide variety of techniques. As one example, memory capacity can be increased by compressing at least some of the previously stored session information. This can comprise compressing some, or all, of the previously stored session information. As another example, memory capacity can be so increased by deleting at least some, but not all, of the session context information as corresponds to the communication session. More particularly, previously stored session information that is not critical to subsequent restoration of a corresponding call can be so deleted.

In a preferred approach, memory capacity is increased by deleting at least some, but not all, session context information as corresponds to the communication session to thereby provide some resultant retained session context information, and then compressing at least some of the retained session context information to provide compressed retained session context information. This reduced and compressed quantity of information can then be stored in a memory that also stores session context information to support additional communication sessions and/or in a memory that is discrete from a memory that stores such session context information, as may best suit the needs of a given context or application.

So configured, the network element significantly reduces through deletion and/or compression the amount of session context information that is retained by (or on behalf of) the network element notwithstanding that the communication session has not concluded. This, in turn, results in memory space that would otherwise have been allocated during such a session. This additional memory space can be used to support additional calls, thereby increasing the number of calls that can be handled and supported by a single network element. The particular information that persists can vary with the particular application. In general, such information will preferably comprise any kind of information that is usable at a later time to facilitate call restoration including particularly relevant session context information. Such information can comprise, for example, Radio Network Node to Packet Data Serving Node protocol session context information, Point-to-Point Protocol session context information, Internet Protocol session context information, or some relevant combination thereof.

In an optional but preferred approach, this process 30 can further comprise then detecting 33 another change in the operational status of the mobile station during the communication session (for example, a change from a dormant status to an active status). Upon detecting such a change, the process 30 can then automatically retrieve 34 at least some of the stored session information to use during the communication session. This retrieval can be effected with respect to whichever local or remote memory (or memories) contains such information. In a preferred embodiment, this comprises retrieving session context information comprising, for example, any of Radio Network Node to Packet Data Serving Node protocol session context information, Point-to-Point Protocol session context information, Internet Protocol session context information, or some combination thereof.

Such retrieval can also comprise, when the information has been previously compressed as described above, the automatic decompression of at least a part of such stored session information.

So configured, the network element can utilize the recovered session context information to reconstruct or otherwise restore a desired level of connectivity for the mobile station at such time as the mobile station shifts from a dormant to an active status. This occurs notwithstanding that the network element had previously deleted and/or compressed the relevant information in order to make room available to accommodate an increased quantity of other communication sessions.

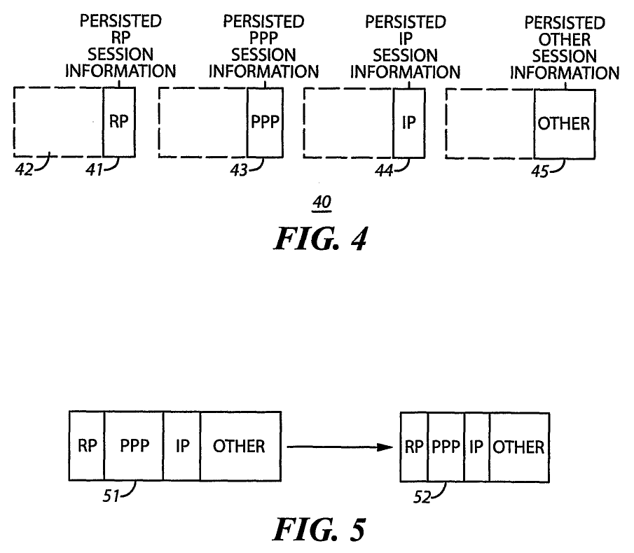

FIG. 4 provides an illustrative schematic view of deleting such previously stored session information. In this representative depiction, the session information 40 comprises RP session information, PPP session information, IP session information, and other session information. In this illustration, a first quantity 42 of RP session information (comprising, in a preferred embodiment, RP session information that is not critical to reestablishment of the corresponding call) is discarded, leaving a reduced quantity 41 of persisted RP session information. In a similar fashion, a reduced quantity 43 of persisted PPP session information, a reduced quantity 44 of persisted IP session information, and a reduced quantity 45 of other session information is provided. At this point, if desired, these reduced quantities of information can be stored and some significant amount of memory will be rendered available to support other sessions.

If desired, and referring now to FIG. 5, the above-described persisted information 51 can be compressed to provide a resultant quantity of persisted and compressed session information 52. Numerous compression techniques are presently known and others will no doubt be developed in the future. These teachings are not particularly sensitive to use or selection of any particular compression technique and hence these teachings may be viewed as being applicable in combination with all such compression techniques.

In the more specific illustrative examples provided above, RP, PPP, and IP session context information was presented as examples of session specific information of interest. Those skilled in the art will appreciate that any information deemed critical to call restoration can be similarly identified and processed to achieve or maintain the benefits set for herein.

Those skilled in the art will appreciate that considerable memory savings can be achieved using these teachings and that these savings can be directly applied in favor of supporting additional communication sessions. This, in turn, permits an existing network element such as a Packet Data Serving Node to be further leveraged with respect to the number of communication sessions that such a network element might otherwise be expected to reasonably accommodate. At the same time, these benefits are not gained at the undue expense of delay or inefficiency with respect to supporting subsequent participation of a given mobile station in a later portion of a given communication session, as the network element has the requisite core of information necessary to effect, for example, a rapid shift to reflect a change by the mobile station from a dormant status to an active status.

Those skilled in the art will recognize that a wide variety of modifications, alterations, and combinations can be made with respect to the above described embodiments without departing from the spirit and scope of the invention, and that such modifications, alterations, and combinations are to be viewed as being within the ambit of the inventive concept.

1-125. (canceled)

126. A method, comprising:
providing a semiconductor nanoscale wire;
patterning a mask on the nanoscale wire to define at least a first portion not covered by the mask and a second portion covered by the mask;
exposing the first portion but not the second portion to a bulk metal; and
diffusing at least a portion of the bulk metal into the first portion of the nanoscale wire.

127. The method of claim 126, wherein the semiconductor nanoscale wire comprises silicon.

128. The method of claim 127, comprising diffusing at least a portion of the bulk metal into the first portion of the nanoscale wire to form a metal silicide having a stoichiometric ratio of silicon and at least one metal.

129. The method of claim 128, wherein the metal silicide comprises nickel silicide.

130. The method of claim 126, wherein the bulk metal comprises a transition metal.

131. The method of claim 126, wherein the bulk metal comprises nickel.

132. The method of claim 126, wherein the first portion of the nanoscale wire has a smallest dimension less than 200 nm.

133. The method of claim 126, wherein the nanoscale wire is a single crystal.

134. The method of claim 126, wherein the mask comprises photoresist.

135. The method of claim 126, wherein the mask comprises a second nanoscale wire.

136. The method of claim 135, wherein the second nanoscale wire comprises a core and a shell.

137. The method of claim 126, wherein the nanoscale wire is a nanowire.

138. The method of claim 126, comprising diffusing at least a portion of the bulk metal into the first portion of the nanoscale wire such that the first region has a resistivity of less than about 60 microOhm cm.

139. The method of claim 126, comprising diffusing at least a portion of the bulk metal into the first portion of the nanoscale wire such that the first region is able to carry a current density of at least about 10⁸ A/cm².

140. A method, comprising:
promoting a method comprising an act of diffusing at least a portion of a bulk metal into at least a portion of a semiconductor nanoscale wire, the bulk metal and the semiconductor nanoscale wire being adjacent, wherein the semiconductor nanoscale wire comprises at least one portion having a smallest dimension of less than about 500 nm.

141. The method of claim 140, wherein the bulk metal comprises nickel.

142. The method of claim 140, wherein the semiconductor nanoscale wire comprises silicon.

143. The method of claim 140, comprising promoting a method comprising an act of diffusing at least a portion of the bulk metal into at least a portion of the semiconductor wire to form a metal silicide.

144. The method of claim 143, wherein the metal silicide has a stoichiometric ratio of silicon and at least one metal.

145. The method of claim 144, wherein the metal silicide comprises nickel silicide.
